(19) United States
(12) Patent Application Publication
(10) Pub. No.: US 2026/0026293 A1
(43) Pub. Date: Jan. 22, 2026

(54) SUBSTRATE TRANSFER ROBOT SYSTEM, SEMICONDUCTOR MANUFACTURING APPARATUS, AND CONTROL METHOD

(71) Applicant: KABUSHIKI KAISHA YASKAWA DENKI, Fukuoka (JP)

(72) Inventors: Go YAMAGUCHI, Fukuoka (JP); Kazunori HINO, Fukuoka (JP); Norihisa IWASAKI, Fukuoka (JP); Yoshitaka IRITANI, Fukuoka (JP)

(21) Appl. No.: 19/269,340

(22) Filed: Jul. 15, 2025

(30) Foreign Application Priority Data
Jul. 19, 2024 (JP) 2024-116168

(51) Int. Cl. H01L 21/67; B25J 11/00; B25J 13/08; H01L 21/687

(52) U.S. Cl. CPC H01L 21/67259; B25J 13/088; H01L 21/68707; B25J 11/0095

(57) ABSTRACT

A substrate transfer robot system includes: a robot provided with a hand link including a hand supporting a substrate, and a plurality of links including one or more links connected to the hand link; a calculator that calculates a length of each of the plurality of links of the robot based on a position of the hand link in a state where the robot is in a first posture and a position of the hand link in a state where the robot is in a second posture different from the first posture; and a controller that controls the robot to place the substrate at a target position based on the length of each of the plurality of links calculated by the calculator.

### CROSS REFERENCES TO RELATED APPLICATIONS

This application is based on and claims priority from Japanese Patent Application No. 2024-116168, filed on Jul. 19, 2024, with the Japan Patent Office, the disclosure of which is incorporated herein in its entirety by reference.

### TECHNICAL FIELD

The present disclosure relates to a substrate transfer robot system, a semiconductor manufacturing apparatus, and a control method.

### BACKGROUND

A system is disclosed, which calculates the extension of each link of a robot based on the reach of the robot when a list of the robot passes a sensor, and corrects a position of the robot based on the calculated extension of each link (see, e.g., Japanese Patent Publication No. 2004-134747).

### SUMMARY

The present disclosure provides a robot system effective in improving the accuracy of placement of a substrate.

According to an aspect of the present disclosure, a substrate transfer robot system includes: a robot provided with a hand link including a hand supporting a substrate, and a plurality of links including one or more links connected to the hand link; a calculator that calculates a length of each of the plurality of links of the robot based on a position of the hand link in a state where the robot is in a first posture and a position of the hand link in a state where the robot is in a second posture different from the first posture; and a controller that controls the robot to place the substrate at a target position based on the length of each of the plurality of links calculated by the calculator.

According to another aspect of the present disclosure, a semiconductor manufacturing apparatus includes: at least one process chamber that accommodates a substrate, and performs a processing on the accommodated substrate; a robot that is provided with a hand link including a hand supporting the substrate, and a plurality of links including one or more links connected to the hand link, and that transfers the substrate to a target position in the at least one process chamber; a calculator that calculates a length of each of the plurality of links of the robot based on a position of the hand link in a state where the robot is in a first posture and a position of the hand link in a state where the robot is in a second posture different from the first posture, and a controller that controls the robot to place the substrate at the target position based on the length of each of the plurality of links calculated by the calculator.

According to yet another aspect of the present disclosure, a control method includes: calculating a length of each of a plurality of links of a robot based on a position of a hand link in a state where the robot is in a first posture and a position of the hand link in a state where the robot is in a second posture different from the first posture, the robot provided with the hand link including a hand supporting a substrate and the plurality of links including one or more links connected to the hand link; and controlling the robot to place the substrate at a target position based on the length of each of the plurality of links calculated in the calculating.

According to the present disclosure, it is possible to provide a robot system effective in improving the accuracy of placement of a substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a configuration of a semiconductor manufacturing apparatus.

FIG. 2 is a schematic view illustrating a configuration of a substrate transfer robot system.

FIG. 3 is a schematic view illustrating a modification of a substrate transfer robot.

FIG. 4 is a schematic view illustrating a process performed by a calculation unit.

FIG. 5 is a view illustrating a detection of a hand position in each of a first posture and a second posture.

FIG. 6 is a view illustrating the detection of the hand position based on a result of detection of a first line and a second line.

FIG. 7 is a view illustrating a first marker and a second marker.

FIG. 8 is a view illustrating a modification of the first marker and the second marker.

FIG. 9 is a view illustrating a detection of a positional deviation of a substrate.

FIG. 10 is a schematic view illustrating a modification of the process performed by the calculation unit.

FIG. 11 is a block diagram illustrating a hardware configuration of a controller.

FIG. 12 is a flowchart illustrating a procedure for acquiring reference data.

FIG. 13 is a flowchart illustrating a substrate transfer procedure.

FIG. 14 is a flowchart illustrating a modification of the substrate transfer procedure.

FIG. 15 is a plan view illustrating a modification of the semiconductor manufacturing apparatus.

FIG. 16 is a plan view illustrating hand links of a substrate transfer robot in FIG. 15.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described in detail with reference to the drawings. In the descriptions, the same components or components having the same function will be denoted with the same reference numerals, and overlapping descriptions thereof will be omitted.

### [Semiconductor Manufacturing Apparatus]

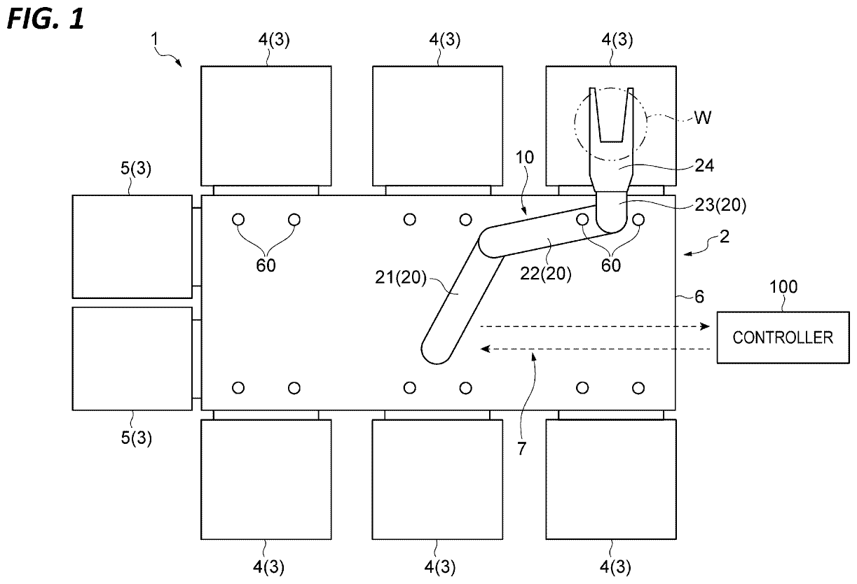

FIG. 1 is a plan view illustrating the configuration of a semiconductor manufacturing apparatus 1. The semiconductor manufacturing apparatus 1 illustrated in FIG. 1 performs at least part of a semiconductor manufacturing process. For example, the semiconductor manufacturing apparatus 1 performs a processing such as deposition and etching on a substrate W (e.g., a semiconductor wafer). For example, the semiconductor manufacturing apparatus 1 includes a semiconductor transfer apparatus 2 and a plurality of peripheral chambers 3. The semiconductor transfer apparatus 2 transfers the substrate W, which is a processing target. Each of the plurality of peripheral chambers 3 performs a processing on the substrate W transferred by the semiconductor transfer apparatus 2.

The plurality of peripheral chambers 3 may include one or more process chambers 4 and one or more load lock chambers 5. Each of the one or more process chambers 4 accommodates the substrate W to perform a processing such as deposition or etching. The one or more load lock chambers 5 each accommodate the substrate W at the boundary between air and vacuum, and performs a process of changing the atmospheric pressure around the substrate W to the atmospheric pressure of a release destination before the substrate W is released into the vacuum or air. Thus, the processing on the substrate W also includes the process of adjusting the environment around the substrate W.

The semiconductor transfer apparatus 2 includes a transfer chamber 6 and a substrate transfer robot system 7. The transfer chamber 6 accommodates the substrate W among the plurality of peripheral chambers 3. As an example, the pressure in the one or more process chambers 4 and the transfer chamber 6 is reduced to a pressure lower than the atmospheric pressure (e.g., vacuum or near vacuum). The inside of each of the one or more process chambers 4 and the inside of the transfer chamber 6 are in the “vacuum” state described above. The one or more load lock chambers 5 is each depressurized to the atmospheric pressure in the transfer chamber 6 before being opened to the inside of the transfer chamber 6, and returned to the atmospheric pressure outside the transfer chamber 6 before being opened to the outside of the transfer chamber 6.

The substrate transfer robot system 7 includes a robot 10 and a controller 100. The robot 10 includes a hand link 23 and a plurality of links 20 including one or more links 21 and 22. The hand link 23 includes a hand 24 supporting the substrate W. The one or more links 21 and 22 are connected to the hand link 23.

The controller 100 controls the robot 10 to transfer the substrate W in the transfer chamber 6, and to carry the substrate W into/out of each of the plurality of peripheral chambers 3. For example, the controller 100 displaces the hand 24 supporting the substrate W by the links 21 and 22 and the hand link 23. The controller 100 controls the robot 10 to transfer the substrate W to a target position in each of the plurality of peripheral chambers 3. As the precision of a processing is enhanced, it is desired to improve the accuracy of placement of the substrate W at the target position.

Thus, the controller 100 is configured to perform calculating the length of each of the plurality of links 20 of the robot 10 based on a position of the hand link 23 in a state where the robot 10 is in a first posture and a position of the hand link 23 in a state where the robot 10 is in a second posture different from the first posture, and controlling the robot 10 to place the substrate W at the target position based on the calculated length of each of the plurality of links 20.

The length of the plurality of links 20 may vary due to, for example, thermal expansion. The temperature distribution in the plurality of links 20 may not be uniform. For example, a heating caused by the entry into a process chamber 4 concentrates in the hand link 23. Further, in a case where motors of the robot 10 are disposed collectively in the base portion of the plurality of links 20, the side of the plurality of links 20 close to the base portion is easily affected by the heat occurring from the motors than the side of the plurality of links 20 farther from the base portion is. Even when the motors of the robot 10 are distributed in the plurality of links 20, the temperatures of the plurality of links 20 may differ according to the heating state of each motor. Since the temperature distribution in the plurality of links 20 varies due to the factors described above, the relationship between the plurality of links 20 in terms of the amount of extension caused by the thermal expansion also varies. The substrate transfer robot system 7 calculates the length of each of the plurality of links 20 (hereinafter, referred to as the “link length”), based on the position of the hand link 23 in the first posture and the position of the hand link 23 in the second posture different from the first posture. Thus, even though the relationship between the links in terms of the amount of extension caused by, for example, the thermal expansion is unknown, the link length may be calculated with a high reliability, and the substrate W may be placed at the target position with a high accuracy based on the calculation result. Therefore, the accuracy of placement of the substrate W may be improved effectively.

While descriptions have been made on the configuration in which the substrate transfer robot system 7 transfers the substrate W in the vacuum environment, the semiconductor manufacturing apparatus 1 is not necessarily limited to the configuration in which the substrate transfer robot system 7 transfers the substrate W in the vacuum environment. Hereinafter, the configuration of the substrate transfer robot system 7 will be further described.

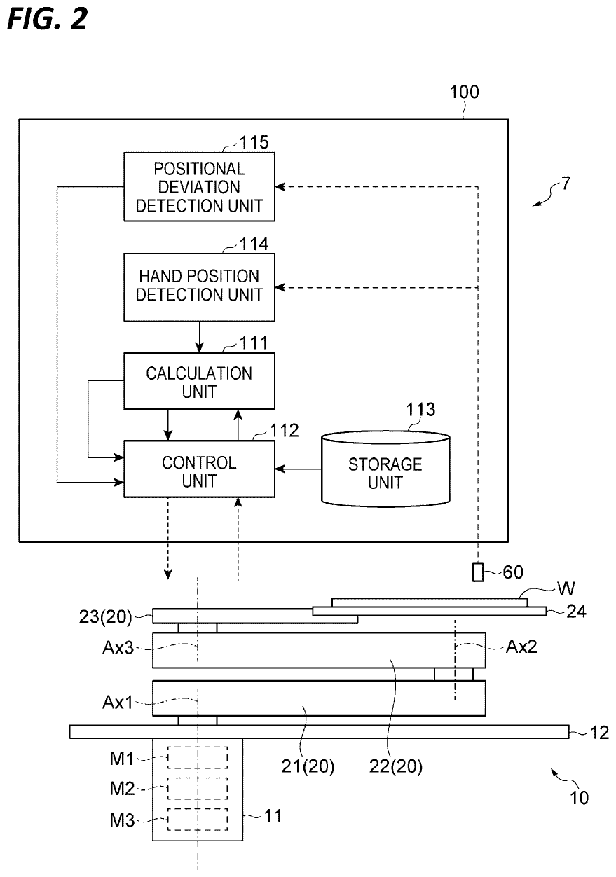

FIG. 2 is a schematic view illustrating the configuration of the substrate transfer robot system 7. FIG. 2 includes the side view of the robot 10. As illustrated in FIG. 2, the robot 10 includes a base 11, the links 21 and 22, the hand link 23, and motors M1, M2, and M3. The base 11 is fixed to the transfer chamber 6. For example, the base 11 is fixed to the bottom plate of the transfer chamber 6.

The link 21 is connected onto the base 11 to be rotatable around a vertical joint axis Ax1, and extends away from the joint axis Ax1. The link 22 is connected onto the end of the link 21 to be rotatable around a vertical joint axis Ax2, and extends away from the joint axis Ax2. The hand link 23 is connected onto the end of the link 22 to be rotatable around a vertical joint axis Ax3, and extends away from the joint axis Ax3. The hand link 23 includes the hand 24. The hand 24 makes up the tip of the hand link 23, and is wide along the horizontal plane. The hand 24 supports the substrate W from below. In the descriptions herein below, a “joint angle” of the robot 10 refers to the angle of rotation of the link 21 with respect to the base 11, the angle of rotation of the link 22 with respect to the link 21, and the angle of rotation of the hand link 23 with respect to the link 22.

The motors M1, M2, and M3 drive the links 21 and 22, and the hand link 23, respectively, to change the joint angle of the robot 10. For example, the motor M1 rotates the link 21 around the joint axis Ax1, the motor M2 rotates the link 22 around the joint axis Ax2, and the motor M3 rotates the hand link 23 around the joint axis Ax3. As illustrated, the motors M1, M2, and M3 may be equipped in the base 11. In this case, the motors M2 and M3 drive the link 22 and the hand link 23, respectively, via transmission mechanisms such as belts and pulleys.

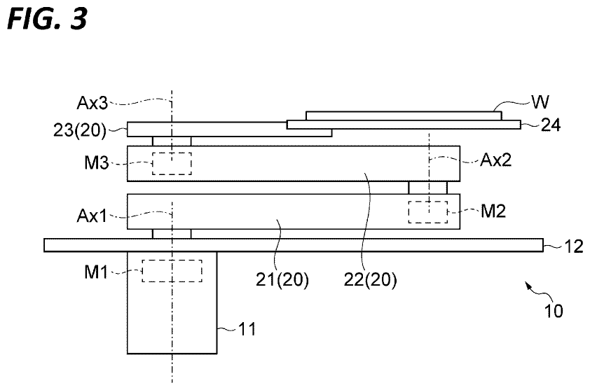

The robot 10 may further include a flange 12. The flange 12 is wide horizontally between the base 11 and the link 21, to partition the base 11 and the link 21 from each other. The flange 12 is fixed to the base 11. The flange 12 closes an opening formed in the bottom of the transfer chamber 6, in order to carry the robot 10 into the transfer chamber 6. In the state where the flange 12 closes the opening, the base 11 is positioned outside the transfer chamber 6, and the links 21 and 22 and the hand link 23 are positioned inside the transfer chamber 6. The robot 10 may have any configuration as long as the hand 24 may be displaced by the plurality of links 20, and the configuration of the robot 10 described above may be modified. For example, as illustrated in FIG. 3, the motor M2 may be equipped in either one of the links 21 and 22 around the joint axis Ax2. The motor M3 may be equipped in either one of the link 22 and the hand link 23 around the joint axis Ax3.

The controller 100 includes a calculation unit 111, a control unit 112, and a storage unit 113 as functional components (hereinafter, referred to as the “functional blocks”). The storage unit 113 stores an operation program generated in advance to cause the robot 10 to transfer the substrate W to the target position. The operation program includes a plurality of chronological operation commands. Each of the plurality of operation commands includes a hand target position and a hand target posture for positioning the hand 24.

The calculation unit 111 calculates the length of each of the plurality of links 20 of the robot 10 based on the position of the hand link 23 in the state where the robot 10 is in the first posture and the position of the hand link 23 in the state where the robot 10 is in the second posture different from the first posture. Based on the operation program stored by the storage unit 113 and the length of each of the plurality of links 20 calculated by the calculation unit 111, the control unit 112 controls the semiconductor transfer apparatus 2 to place the substrate W at the target position.

For example, the control unit 112 controls the robot 10 to be in the first posture and the second posture, based on the operation program stored by the storage unit 113. The calculation unit 111 calculates the length of each of the plurality of links 20, based on the position of the hand link 23 in the state where the robot 10 is in the first posture under the control of the control unit 112 and the position of the hand link 23 in the state where the robot 10 is in the second posture under the control of the control unit 112. After calculating the length of each of the plurality of links 20, the control unit 112 controls the semiconductor transfer apparatus 2 to place the substrate W at the target position based on the operation program stored by the storage unit 113 and the calculated length of each of the plurality of links 20.

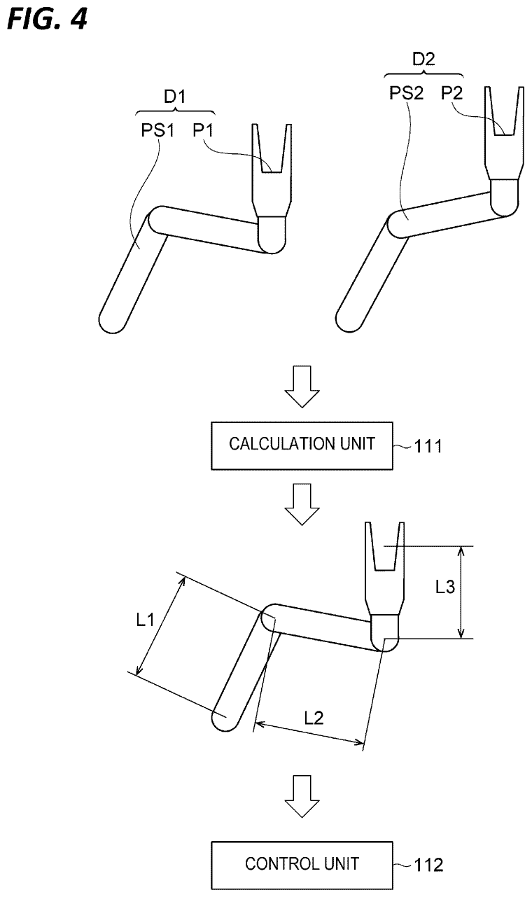

For example, as illustrated in FIG. 4, the calculation unit 111 acquires a first data set D1 and a second data set D2. The first data set D1 includes information representing a first posture PS1 and information representing a position P1 of the hand link 23 in the state where the robot 10 is in the first posture PS1. The second data set D2 includes information representing a second posture PS2 and information representing a position P2 of the hand link 23 in the state where the robot 10 is in the second posture PS2. The information representing the first posture PS1 and the information representing the second posture PS2 are, for example, information about the joint angle of the robot 10.

In a case where the relationship of the lengths of the plurality of links 20 is unknown, the first data set D1 alone is insufficient to uniquely determine the length of each of the plurality of links 20. Similarly, the second data set D2 alone is insufficient to uniquely determine the length of each of the plurality of links 20. By combining the first data set D1 and the second data set D2, the calculation unit 111 acquires a constraint condition to uniquely determine the length of each of the plurality of links 20 even when the relationship of the lengths of the plurality of links 20 is unknown, and calculates the length of each of the plurality of links 20 based on the acquired constraint condition. For example, based on the combination of the first data set D1 and the second data set D2, the calculation unit 111 acquires the constraint condition to uniquely determine values of the length L1 of the link 21, the length L2 of the link 22, and the length L3 of the hand link 23 in an equation including the lengths L1, L2, and L3 as independent variables. Based on the acquired constraint condition, the calculation unit 111 calculates each of the lengths L1, L2, and L3 individually.

Referring back to FIG. 2, the substrate transfer robot system 7 may further include at least one sensor 60 that detects the hand link 23. The at least one sensor 60 is fixed at a position spaced apart from the robot 10, and detects the hand link 23 in a non-contact manner. The sensor 60 may be, for example, an optical sensor. For example, the sensor 60 may be fixed outside the transfer chamber 6 to detect the hand link 23 through, for example, a glass window.

As an example, the at least one sensor 60 may be at least one object sensor that detects the presence or absence of an object at its specific detection position. Examples of the object sensor include a laser sensor, a capacitive sensor, and an ultrasonic sensor. By the object sensor, it is detected that a predetermined detection target portion of the hand link 23 is present at the detection position of the object sensor.

For example, the substrate transfer robot system 7 may include a pair of sensors 60 (object sensors) for each of the plurality of peripheral chambers 3. The pair of sensors 60 are arranged in the direction perpendicular to the direction in which the substrate W is carried into/out of a corresponding peripheral chamber 3 (see FIG. 1).

The object sensor is merely an example, and the sensor 60 is not necessarily limited to the object sensor. For example, the sensor 60 may be, for example, a camera or a laser tracker. In case of a camera, it is possible to detect the position of the detection target portion within the camera's field of view based on the position of the detection target portion within a captured image. In case of a laser tracker, it is possible to detect the position of the detection target portion within a detection target range of the laser tracker.

The controller 100 may further include a hand position detection unit 114. The hand position detection unit 114 detects each of the position of the hand link 23 in the first posture and the position of the hand link 23 in the second posture, based on the result of detection of the hand link 23 by the at least one sensor 60. When the at least one sensor 60 is at least one object sensor, the hand position detection unit 114 detects the position of the hand link 23 in the first posture, based on which part of the hand link 23 in the first posture is detected by an object sensor, and which object sensor detects the part. Similarly, the hand position detection unit 114 detects the position of the hand link 23 in the second posture, based on which part of the hand link 23 in the second posture is detected by an object sensor and which object sensor detects the part.

The hand link 23 may include a first part and a second part at different positions from each other. Each of the first and second parts may be disposed at a position that is not hidden by the substrate W (the substrate W supported by the hand 24) when viewed from the sensor 60. The hand position detection unit 114 may detect each of the position of the hand link 23 in the first posture and the position of the hand link 23 in the second posture, based on the result of detection of the first and second parts by the same sensor. For example, the hand link 23 includes a first part 31 and a second part 32 at different positions from each other in the longitudinal direction of the hand link 23. For example, the hand link 23 includes protrusions 40 and 50 that each protrude laterally (toward one side of the direction perpendicular to the longitudinal direction and the vertical direction) at different positions in the longitudinal direction. The protrusion 40 is disposed farther from the joint axis Ax3 than the protrusion 50 is. For example, in the longitudinal direction, the distance from the joint axis Ax3 to the protrusion 40 is longer than the distance from the joint axis Ax3 to the protrusion 50.

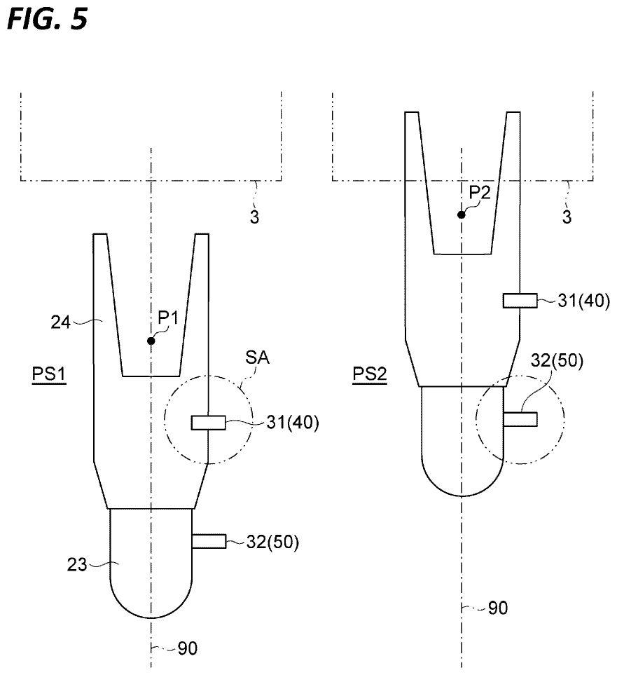

For example, as illustrated in FIG. 5, the control unit 112 positions the first part 31 in the first posture PS1 within a detection area SA of the sensor 60. Based on the result of detection of the first part 31 by the sensor 60, the hand position detection unit 114 detects the position P1 in the first posture PS1. Similarly, the control unit 112 positions the second part 32 in the second posture PS2 within the detection area SA where the first part 31 has been positioned. Based on the result of detection of the second part 32 by the sensor 60, the hand position detection unit 114 detects the position P2 in the second posture PS2. According to the configuration of the first part 31 and the second part 32, the robot 10 may efficiently detect the position P1 in the first posture PS1 and the position P2 in the second posture PS2, using the period of time during which the robot 10 is moving the hand link 23 in one direction. For example, when the sensor 60 is an object sensor, both the position P1 in the first posture PS1 and the position P2 in the second posture PS2 may be detected, by the series of operations to detect the first part 31 and the second part 32 in turn using the same object sensor. Therefore, both the efficiency of operation of the robot 10 and the accuracy of placement of the substrate W may be achieved. The operation efficiency is represented by, for example, the reduction of movement distance of the substrate W for transferring the substrate W or the energy consumption of the robot 10 for transferring the substrate W.

Both the first posture PS1 and the second posture PS2 may be postures for carrying the hand 24 into/out of a peripheral chamber 3 along a predetermined entry/exit line 90. For example, both the first posture PS1 and the second posture PS2 may be postures for advancing and retracting the hand link 23 along the predetermined entry/exit line 90 to transfer the substrate W between the inside and the outside of the peripheral chamber 3. By using the period of time during which the robot 10 is moving the hand link 23 in one direction in order to carry the substrate W into or out of the peripheral chamber 3, the position P1 in the first posture PS1 and the position P2 in the second posture PS2 may be efficiently detected. As an example, the distance from the position P1 in the first posture PS1 to the peripheral chamber 3 is longer than the distance from the position P2 in the second posture PS2 to the peripheral chamber 3.

The hand position detection unit 114 may detect the position P1 in the first posture PS1 and the position P2 in the second posture PS2, while the robot 10 is moving the hand 24 from the inside of the peripheral chamber 3 to the outside of the peripheral chamber 3 along the entry/exit line 90. By using the operation of carrying the substrate W out of the peripheral chamber 3, the position P1 in the first posture PS1 and the position P2 in the second posture PS2 may be detected. In this case, the hand position detection unit 114 detects the position P1 in the first posture PS1 after detecting the position P2 in the second posture PS2. The calculation unit 111 calculates the length of each of the plurality of links 20 after the substrate Wis transferred from the inside of the peripheral chamber 3 to the outside of the peripheral chamber 3. The control unit 112 may control the robot 10 to place the substrate W at the next target position based on the calculated length of each of the plurality of links 20.

The control unit 112 may control the robot 10 to place the next substrate W at the target position based on the calculated length of each of the plurality of links 20. The next substrate W refers to the substrate W to be supported by the hand 24 next time after the substrate W transferred from the inside of the peripheral chamber 3 to the outside of the peripheral chamber 3 leaves the hand 24, for example, at the next target position.

The hand position detection unit 114 may detect the position P1 in the first posture PS1 and the position P2 in the second posture, while the robot 10 is moving the hand link 23 (the hand 24) from the outside of the peripheral chamber 3 into the peripheral chamber 3 along the entry/exit line 90 in order to transfer the substrate W from the inside of the peripheral chamber 3 to the outside of the peripheral chamber 3. By using the operation of moving the hand link 23 into the peripheral chamber 3 to carry the substrate W out of the peripheral chamber 3, the position P1 in the first posture PS1 and the position P2 in the second posture PS2 may be detected. In this case, the hand position detection unit 114 detects the position P1 in the first posture PS1, and then, the position P2 in the second posture PS2. The calculation unit 111 calculates the length of each of the plurality of links 20 after the hand link 23 moves from the outside of the peripheral chamber 3 into the peripheral chamber 3. The control unit 112 may control the robot 10 to position the hand link 23 at the target position for acquiring the substrate W to be carried out, based on the calculated length of each of the plurality of links 20. Further, the control unit 112 may control the robot 10 to place the substrate W at the next target position based on the calculated length of each of the plurality of links 20.

Each of the plurality of links 20 may have a known reference length in a first environment, at least one of the plurality of links 20 may have a length different from the reference length in a second environment different from the first environment, and the calculation unit 111 may calculate the length of each of the plurality of links 20 in the second environment based on the result of detection of the position P1 in the first posture PS1 and the position P2 in the second posture PS2 in the second environment. Regardless of the difference between the first environment and the second environment, the substrate may be placed at the target position with a high accuracy.

The first environment refers to an environment in which expansion and contraction caused by heat are negligible even when they occur in any of the plurality of links 20 (e.g., a room temperature environment). The room temperature refers to a temperature within the fluctuation range of the atmospheric temperature on the ground. The second environment refers to an environment in which each of the plurality of links 20 extends due to the thermal expansion caused by, for example, a heating in the process chamber 4. The second environment has a lower temperature than the room temperature, and thus, may be an environment in which each of the plurality of links 20 contracts.

The calculation unit 111 may calculate the length of each of the plurality of links 20, based on the result of detection of the position P1 in the first posture PS1 and the position P2 in the second posture PS2 in both the first environment and the second environment. Since the reference length is known as described above, more equations than the number of variables may be obtained from the result of detection in both the first environment and the second environment, and values of variables of the lengths L1, L2, and L3 may also be uniquely determined. Therefore, the length of each of the plurality of links 20 may be calculated, for example, even when the position of the at least one sensor 60 is unknown.

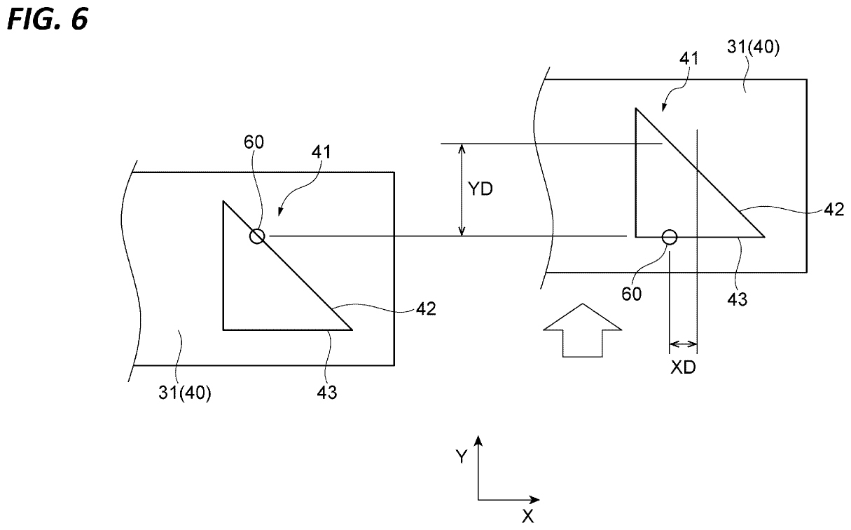

As illustrated in FIG. 6, the first part 31 may include a first marker 41. The first marker 41 may include a first line 42 and a second line 43 that intersect each other when viewed from above. The first marker 41 may be, for example, a right triangle (e.g., an isosceles right triangle). The first line 42 may be the oblique side of the right triangle, and the second line 43 may be one of the orthogonal sides. The control unit 112 may move the hand link 23 (the hand 24) along a line intersecting the first line 42 and the second line 43 (e.g., perpendicular to the second line 43). For example, the first marker 41 is provided such that the first line 42 and the second line 43 intersect the entry/exit line 90 (e.g., the second line 43 is perpendicular to the entry/exit line 90), and the control unit 112 moves the hand link 23 (the hand 24) along the entry/exit line 90. The hand position detection unit 114 may detect the position of the hand link 23 (two-dimensional position) in the plane including the first line 42 and the second line 43 (e.g., horizontal plane) as the position P1 in the first posture PS1, based on the result of detection of the first line 42 and the result of detection of the second line 43 by the same sensor 60, which is an object sensor.

As an example, the hand position detection unit 114 detects the position P1 in the first posture PS1, at the time when the second line 43 is detected by the sensor 60 after the first line 42 is detected by the sensor 60. Hereinafter, for the convenience of description, the direction intersecting the first line 42 and the second line 43 (e.g., the direction along the entry/exit line 90) will be referred to as the “Y direction,” and the direction perpendicular to the Y direction in the horizontal plane will be referred to as the “X direction.” For example, the hand position detection unit 114 detects that the position of the second line 43 in the Y direction is the position of the sensor 60. Further, the hand position detection unit 114 geometrically calculates the position of the first marker 41 in the X direction (e.g., a relative position XD with respect to the sensor 60) based on the displacement length YD of the hand link 23 until the second line 43 is detected by the sensor 60 after the first line 42 is detected by the sensor 60.

In this way, the position of the hand link 23 in both the X and Y directions may be acquired in a short time, by the series of operations in which the first marker 41 passes the same sensor 60. Therefore, both the efficiency of operation of the robot 10 and the accuracy of placement of the substrate W may be further improved. The control unit 112 may move the hand link 23 such that the first line 42 is detected by the sensor 60 after the second line 43 is detected by the sensor 60.

The first marker 41 may have any configuration as long as it may be detected by the sensor 60. For example, the first marker 41 may be formed by a boundary between an opening penetrating the protrusion 40 and the periphery of the opening. The first marker 41 may be formed by a boundary between a projection protruding upwardly from the protrusion 40 and the periphery of the projection. Further, the first marker 41 may be formed by a boundary between regions in different colors from each other. For example, the first marker 41 may be formed by a boundary between a black region and a white region. Further, the first marker 41 may be formed by the edge line of the protrusion 40 itself.

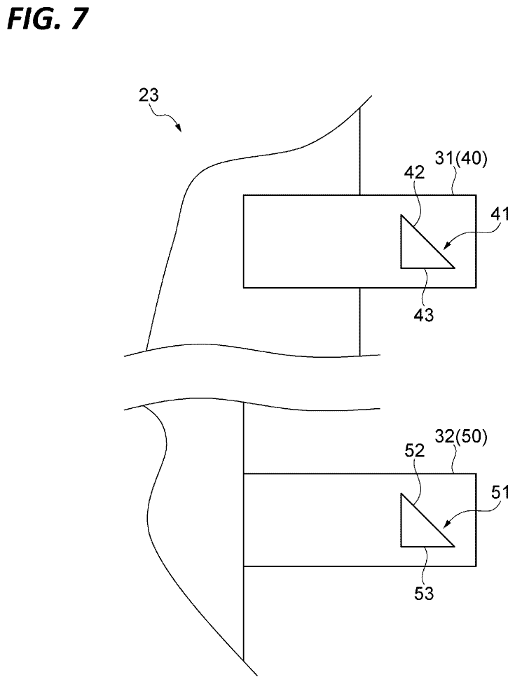

As illustrated in FIG. 7, the second part 32 may have a second marker 51 similar to the first marker 41. The second marker 51 may include a third line 52 and a fourth line 53 that intersect each other when viewed from above. The second marker 51 may be, for example, a right triangle (e.g., an isosceles right triangle). The third line 52 may be the oblique side of the right triangle, and the fourth line 53 may be one of the orthogonal sides. The control unit 112 may move the hand link 23 along a line intersecting the third line 52 and the fourth line 53 (e.g., perpendicular to the fourth line 53). For example, the second marker 51 is provided such that the third line 52 and the fourth line 53 intersect the entry/exit line 90 (e.g., the fourth line 53 is perpendicular to the entry/exit line 90), and the control unit 112 moves the hand link 23 (the hand 24) along the entry/exit line 90. The hand position detection unit 114 may detect the position of the hand link 23 (two-dimensional position) in the plane including the third line 52 and the fourth line 53 (e.g., horizontal plane) as the position P2 in the second posture PS2, based on the result of detection of the third line 52 and the result of detection of the fourth line 53 by the same sensor 60, which is an object sensor.

Similar to the case where the position P1 in the first posture PS1 is calculated using the first marker 41, the hand position detection unit 114 detects the position P2 in the second posture PS2 at the time when the fourth line 53 is detected by the sensor 60 after the third line 52 is detected by the sensor 60. For example, the hand position detection unit 114 detects the position P2 in the X and Y directions.

The hand position detection unit 114 acquires information on the joint angle of the robot 10 at the time when the fourth line 53 is detected by the sensor 60, as the information representing the second posture PS2, and incorporates the information representing the second posture PS2 and the information representing the position P2 into the second data set D2 described above. As represented in the present example, the second posture PS2 may not be predetermined, but may be determined at the time when the fourth line 53 is detected by the sensor 60. The control unit 112 may move the hand link 23 such that the third line 52 is detected by the sensor 60 after the fourth line 53 is detected by the sensor 60.

By detecting both the position P1 and the position P2 in two dimensions, redundant information may be acquired for identifying the length of each of the plurality of links 20. As a result, the link length may be calculated with an enhanced reliability. Therefore, both the efficiency of operation of the robot 10 and the accuracy of placement of the substrate W may be further improved.

The first part 31 and the second part 32 may be arranged to pass the same sensor 60 at different timings while the hand link 23 is moving along the entry/exit line 90. By using the operation of carrying the substrate W into/out of the process chamber 4, the position P1 in the first posture PS1 and the position P2 in the second posture PS2 may be detected. Therefore, both the efficiency of operation of the robot 10 and the accuracy of placement of the substrate W may be further improved.

For example, the first line 42 and the second line 43 of the first marker 41 and the third line 52 and the fourth line 53 of the second marker 51 may be formed to be lined up along the entry/exit line 90 while the hand link 23 is moving along the entry/exit line 90. In this case, the two-dimensional position P1 and the two-dimensional position P2 may be acquired by the series of operations to carry the substrate W into or out of the peripheral chamber 3. According to the two-dimensional position P1 and the two-dimensional position P2, the following four equations may be obtained for the three lengths L1, L2, and L3.

$$f 1 x ( lengths L 1 , L 2 , L 3 ) = X 1$$

$$f 1 y ( lengths L 1 , L 2 , L 3 ) = Y 1$$

$$f 2 x ( lengths L 1 , L 2 , L 3 ) = X 2$$

$$f 2 y ( lengths L 1 , L 2 , L 3 ) = Y 2$$

X1: position P1 in the X direction
Y1: position P1 in the Y direction
X2: position P2 in the X direction
Y2: position P2 in the Y direction

Since the number of equations is redundant as compared to the number of variables, the lengths L1, L2, and L3 may be calculated with a higher accuracy.

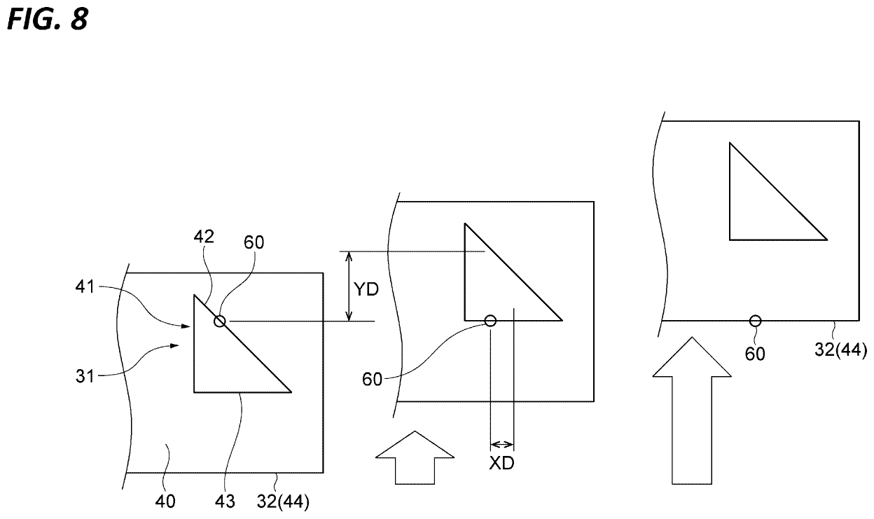

While descriptions have been made on an example where the first part 31 and the second part 32 include the first marker 41 and the second marker 51, respectively, which are similar to each other, the marker of the second part 32 may be different from the marker of the first part 31. FIG. 8 is a view illustrating a modification of the marker of the second part 32. In the example of FIG. 8, both the first part 31 and the second part 32 are formed in a single protrusion 40. The first part 31 includes the first marker 41 described above. The second part 32 is lined up with the first marker 41 along the entry/exit line 90. The second part 32 includes a single line parallel to the second line 43. The single line of the second part 32 is formed by, for example, the edge line 44 of the protrusion 40.

According to the configuration of FIG. 8, since the information on the position P2 is limited by the Y direction, the number of equations decreases. Since the same number of equations as the number of variables may be obtained even though the number of equations decreases, the lengths L1, L2, and L3 may be calculated.

Referring back to FIG. 2, the controller 100 may further include a positional deviation detection unit 115. The positional deviation detection unit 115 detects a positional deviation of the substrate W based on the result of detection of the substrate W by the at least one sensor 60 (object sensor). By using the at least one sensor 60 for multiple purposes, the substrate transfer robot system 7 may be simplified.

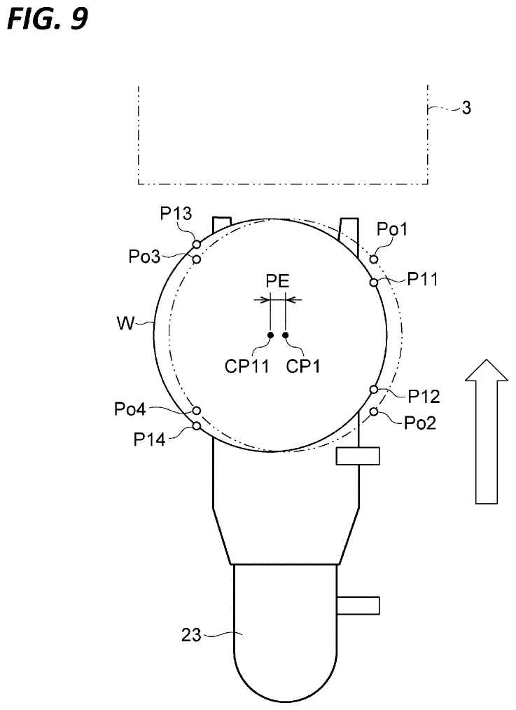

For example, the positional deviation detection unit 115 detects the positional deviation of the substrate W, based on the result of detection of the substrate W that is moving from the outside of the peripheral chamber 3 into the peripheral chamber 3 along the entry/exit line 90 (the substrate W supported by the hand 24 that is moving from the outside of the peripheral chamber 3 into the peripheral chamber 3 along the entry/exit line 90) by the same sensor 60. For example, as illustrated in FIG. 9, the positional deviation detection unit 115 detects points P11, P12, P13, and P14 on the outer periphery of the substrate W, based on the result of detection of the substrate W by the pair of sensors 60 when the control unit 112 carries the substrate W into the peripheral chamber 3. The positional deviation detection unit 115 calculates a center position CP11 of the substrate W based on the positions of the points P11, P12, P13, and P14, and detects a positional deviation PE of the center position CP11 from a reference center position CP1. The center position CP1 is stored in advance after being detected by the positional deviation detection unit 115. For example, the positional deviation detection unit 115 detects points PO1, PO2, PO3, and PO4 on the outer periphery of the substrate W, based on the result of detection of the substrate W by the pair of sensors 60 when the control unit 112 carries the substrate W into the peripheral chamber 3 in the state where the positional deviation PE is zero. The positional deviation detection unit 115 calculates the center position CP1 based on the positions of the points PO1, PO2, PO3, and PO4.

The control unit 112 may control the robot 10 to place the substrate W at the target position, based on the length of each of the plurality of links 20 calculated by the calculation unit 111 and the positional deviation of the substrate W detected by the positional deviation detection unit 115. For example, the control unit 112 calculates an error between the actual position that the hand link 23 reaches according to the operation program and the hand target position, based on the calculated length of each of the plurality of links 20. The control unit 112 corrects the target position based on the detected positional deviation of the substrate W and the calculated error, and controls the robot 10 based on the corrected target position and the operation program. It is possible to speed up the calculation for placing the substrate at the target position.

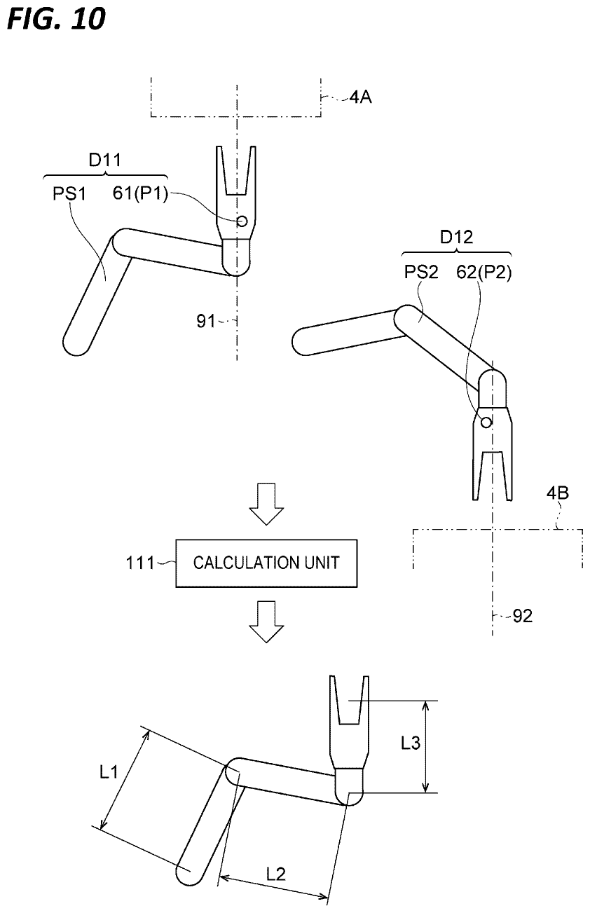

While descriptions have been made on an example where the position P1 in the first posture PS1 and the position P2 in the second posture PS2 are detected based on the detection result by the same sensor 60, the present disclosure is not limited thereto. The substrate transfer robot system 7 may be configured to detect the position P1 in the first posture PS1 and the position P2 in the second posture PS2 based on detection results by different sensors 60. For example, as illustrated in FIG. 10, the semiconductor manufacturing apparatus 1 includes a first process chamber 4A and a second process chamber 4B. The control unit 112 controls the robot 10 to advance and retract the hand link 23 along a predetermined first entry/exit line 91 thereby transferring the substrate W between the inside and the outside of the first process chamber 4A, and to advance and retract the hand link 23 along a predetermined second entry/exit line 92 thereby transferring the substrate W between the inside and the outside of the second process chamber 4B. The at least one sensor 60 includes a first sensor 61 provided to detect the substrate W moving along the first entry/exit line 91 (the substrate W supported by the hand 24 moving along the first entry/exit line 91), and a second sensor 61 provided to detect the substrate W moving along the second entry/exit line 92 (the substrate W supported by the hand 24 moving along the second entry/exit line 92). The hand position detection unit 114 detects the position P1 in the first posture PS1 based on the result of detection of the hand link 23 by the first sensor 61, and the position P2 in the second posture PS2 based on the result of detection of the hand link 23 by the second sensor 62. By using the first sensor 61 corresponding to the first process chamber 4A and the second sensor 62 corresponding to the second process chamber 4B, the position P1 in the first posture PS1 and the position P2 in the second posture PS2 may be easily detected.

The calculation unit 111 acquires a first data set D11 and a second data set D12, and calculates the length of each of the plurality of links 20 based on the first data set D11 and the second data set D12. The first data set D11 includes information representing the first posture PS1 and information representing the position P1 detected based on the first sensor 61. The second data set D12 includes information representing the second posture PS2 and information representing the position P2 detected based on the second sensor 62.

The positional deviation detection unit 115 may detect the positional deviation of the substrate W based on the result of detection of the substrate W by the second sensor 62 when the substrate W is moving from the outside of the second process chamber 4B into the second process chamber 4B. The control unit 112 may control the robot 10 to place the substrate W at the target position in the second process chamber 4B, based on the calculated length of each of the plurality of links 20 and the positional deviation of the substrate W. By using the second sensor 62 for multiple purposes, the system simplification may be implemented.

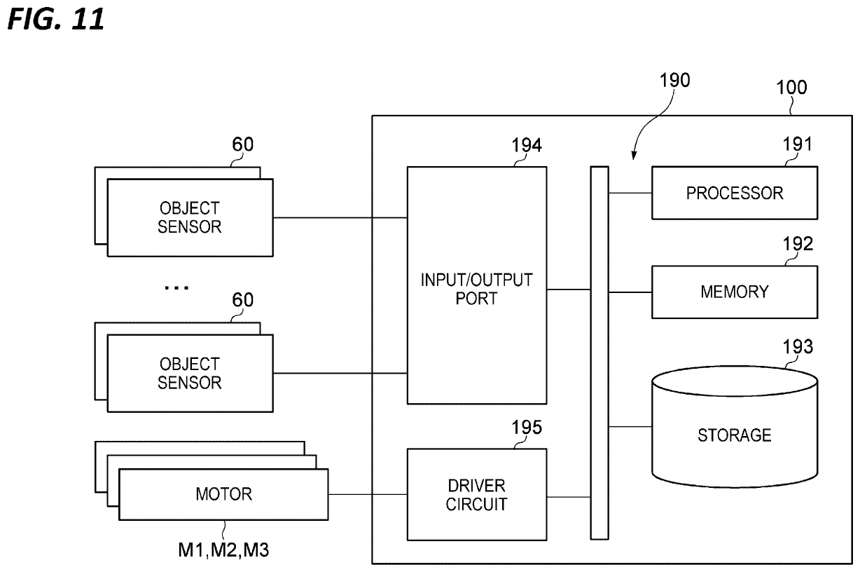

FIG. 11 is a block diagram illustrating the hardware configuration of the controller 100. As illustrated in FIG. 11, the controller 100 includes a circuit 190. The circuit 190 includes a processor 191, a memory 192, a storage 193, an input/output port 194, and a driver circuit 195.

The storage 193 includes, for example, at least one nonvolatile storage medium. The nonvolatile storage medium includes at least one storage device. Examples of the at least one storage device include a hard disk drive, a solid state drive, and a flash memory. The nonvolatile storage medium may include a portable storage medium such as an optical disk. The storage 193 stores a program for causing the controller 100 to control the robot 10. The program causes the controller 100 to execute calculating the length of each of the plurality of links 20 of the robot 10 based on the position of the hand link 23 when the robot 10 is in the first posture and the position of the hand link 23 when the robot 10 is in the second posture different from the first posture, and controlling the robot 10 to place the substrate W at the target position based on the calculated length of each of the plurality of links 20. For example, the program configures the controller 100 with the functional blocks described above.

The memory 192 includes at least one volatile storage medium. The volatile storage medium includes at least one memory device. Examples of the at least one memory device include a random access memory. The memory 192 temporarily stores the program loaded from the storage 193. The processor 191 includes at least one computing device. Examples of the computing device include a central processing unit (CPU) and a graphics processing unit (GPU). The processor 191 executes the program loaded into the memory 192, thereby configuring the controller 100 with the functional blocks described above. The processor 191 may temporarily store calculation results in the memory 192.

The input/output port 194 performs input/output of an electrical signal with respect to the at least one sensor 60 according to a request from the processor 191. The driver circuit 195 supplies a drive power to the motors M1, M2, and M3 according to a request from the processor 191.

### <Control Procedure>

A control procedure performed by the controller 100 will be described as an example of a control method. The procedure includes calculating the length of each of the plurality of links 20 of the robot 10 based on the position of the hand link 23 when the robot 10 is in the first posture and the position of the hand link 23 when the robot 10 is in the second posture, and controlling the robot 10 to place the substrate W at the target position based on the calculated length of each of the plurality of links 20.

As an example, the control procedure includes a reference data acquiring procedure and a control procedure. The reference data acquiring procedure is a procedure for acquiring the first data set D1 and the second data set D2 in the first environment in which each of the plurality of links 20 has the reference length. The control procedure is a procedure for controlling the robot 10 in the second environment different from the first environment. The control procedure is performed after the reference data acquiring procedure.

### (Reference Data Acquiring Procedure)

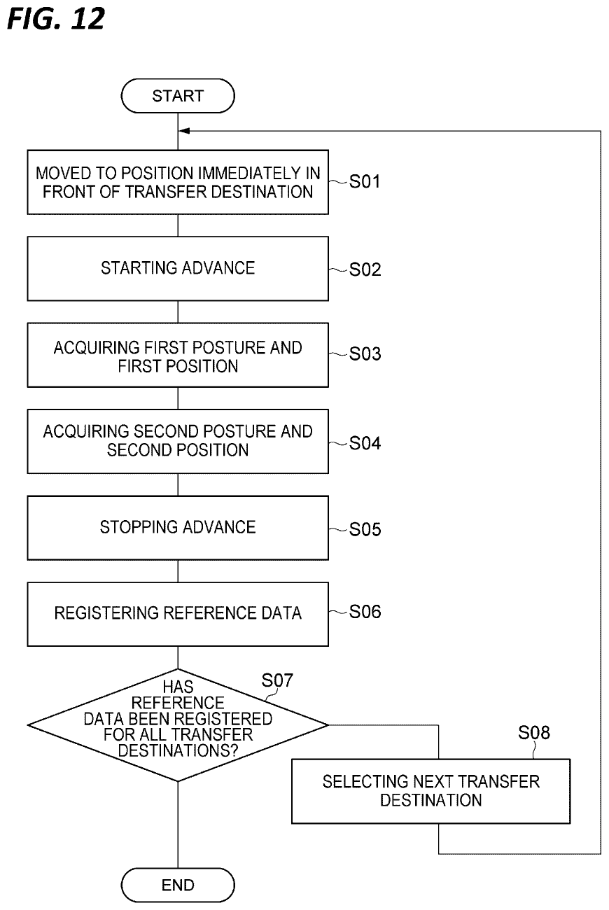

As illustrated in FIG. 12, the controller 100 first performs steps S01 and S02. In step S01, the control unit 112 controls the robot 10 to move the hand link 23 to a position immediately in front of a transfer destination (e.g., one of the plurality of peripheral chambers 3). In step S02, the control unit 112 controls the robot 10 to start advancing the hand link 23 into the transfer destination.

Next, the controller 100 performs steps S03, S04, S05, and S06. In step S03, the calculation unit 111 acquires the first data set D1 including the information on the first posture PS1 and the position P1, based on the posture of the robot 10 and the position of the hand link 23 at the time when the sensor 60 detects the first line 42, and the posture of the robot 10 and the position of the hand link 23 at the time when the sensor 60 detects the second line 43. In step S04, the calculation unit 111 acquires the first data set D2 including the information on the second posture PS2 and the position P2, based on the posture of the robot 10 and the position of the hand link 23 at the time when the sensor 60 detects the third line 52, and the posture of the robot 10 and the position of the hand link 23 at the time when the sensor 60 detects the fourth line 53. In step S05, the control unit 112 controls the robot 10 to stop the advance of the hand link 23 into the transfer destination. In step S06, the calculation unit 111 registers reference data in which the first data set D1, the second data set D2, and the reference length of each of the plurality of links 20 are associated with identification information of the transfer destination (e.g., stores the reference data in a storage medium).

Next, the controller 100 performs step S07. In step S07, the control unit 112 confirms whether the reference data has been registered for all transfer destinations (e.g., all of the plurality of peripheral chambers 3). When it is determined in step S07 that the reference data has not yet been registered for one or more peripheral chambers 3, the controller 100 performs step S08. In step S08, the control unit 112 selects any one of the one or more peripheral chambers 3 for which the reference data has not yet been registered, as the next transfer destination. Then, the controller 100 returns the process to step S01, and repeats the procedure described above until the registration of the reference data is completed for all the transfer destinations.

When it is determined in step S07 that the reference data has been registered for all transfer destinations, the controller 100 completes the reference data acquiring procedure. The reference data may not necessarily be acquired for all the transfer destinations. For example, when the correction of link length is performed at some of the plurality of transfer destinations but not at the other, the reference data may be acquired only for at least the transfer destinations at which the correction is performed. Further, when the reference data is acquired for some of the transfer destinations but not for the other, the correction of link length at the other transfer destinations may be performed using the reference data acquired for some of the transfer destinations.

### (Control Procedure)

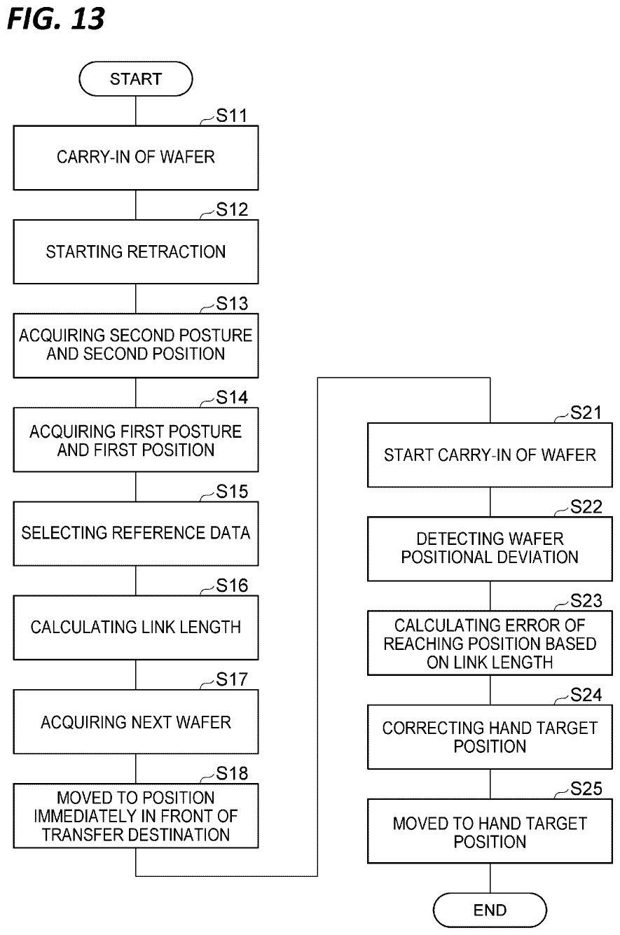

The control procedure is a procedure for calculating the length of each of the plurality of links 20 when the substrate W is transferred from the inside of the peripheral chamber 3 to the outside of the peripheral chamber 3, and controlling the robot 10 based on the calculated length. As illustrated in FIG. 13, the controller 100 first executes steps S11 and S12.

In step S11, the control unit 112 controls the robot 10 to carry the substrate W into the peripheral chamber 3. In step S12, the control unit 112 controls the robot 10 to start retracting the hand link 23 from the peripheral chamber 3 while leaving the substrate W inside.

Next, the controller 100 performs step S13 and S14. In step S13, the calculation unit 111 acquires the second data set D2 including the information on the second posture PS2 and the position P2, based on the posture of the robot 10 and the position of the hand link 23 at the time when the sensor 60 detects the fourth line 53, and the posture of the robot 10 and the position of the hand link 23 at the time when the sensor 60 detects the third line 52. In step S14, the calculation unit 111 acquires the first data set D1 including the information on the first posture PS1 and the position P1, based on the posture of the robot 10 and the position of the hand link 23 at the time when the sensor 60 detects the second line 43, and the posture of the robot 10 and the position of the hand link 23 at the time when the sensor 60 detects the first line 42.

Next, the controller 100 performs steps S15 and S16. In step S15, the calculation unit 111 selects the reference data associated with the transfer destination into which the substrate W has been carried. In step S16, the calculation unit 111 calculates the length of each of the plurality of links 20 based on the second data set D2 acquired in step S13, the first data set D1 acquired in step S14, and the reference data selected in step S15.

Next, the controller 100 performs steps S17 and S18. In step S17, the control unit 112 controls the robot 10 to acquire the next substrate W (support the next substrate W by the hand 24). In step S18, the control unit 112 controls the robot 10 to move the hand link 23 to a position immediately in the front of the transfer destination of the next substrate W.

Next, the controller 100 performs steps S21 and S22. In step S21, the control unit 112 causes the robot 10 to start carrying the next substrate W into the transfer destination. In step S22, the positional deviation detection unit 115 detects the positional deviation of the substrate W based on the result of detection of the substrate W by the sensor 60.

Next, the controller 100 performs steps S23, S24, and S25. In step S23, based on the calculated link length, the control unit 112 calculates the error between the actual position that the hand link 23 reaches and the hand target position. In step S24, the control unit 112 corrects the hand target position based on the positional deviation of the substrate W detected in step S22 and the error calculated in step S23. In step S25, the control unit 112 moves the hand link 23 to the corrected hand target position to place the substrate W at the target position.

### (Modification of Control Procedure)

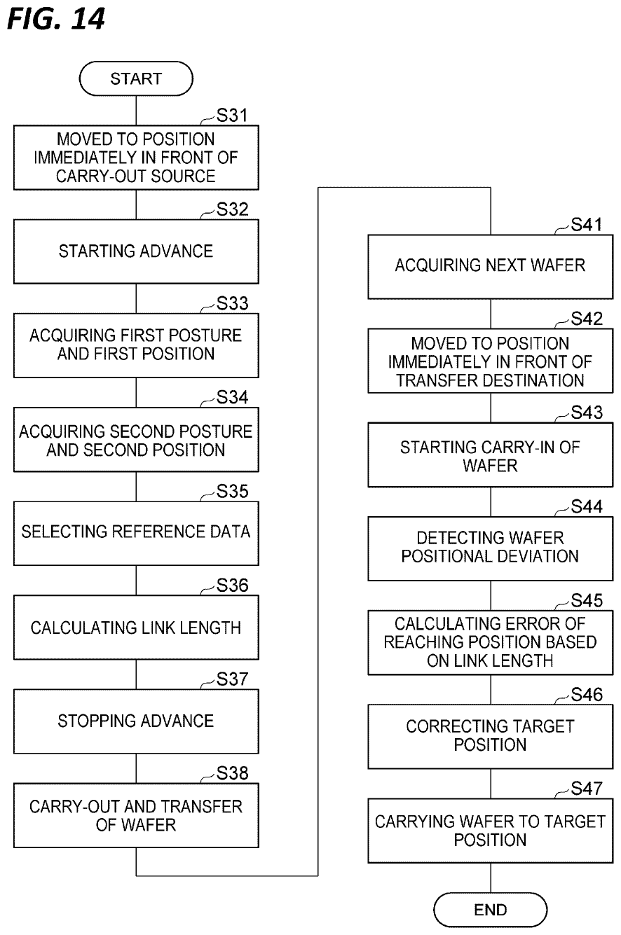

Descriptions will be made on a modification of the control procedure. The modification is a procedure for calculating the length of each of the plurality of links 20 when the hand link 23 is moved from the outside of the peripheral chamber 3 into the peripheral chamber 3 in order to transfer the substrate W from the inside of the peripheral chamber 3 to the outside of the peripheral chamber 3, and controlling the robot 10 based on the calculated length. As illustrated in FIG. 14, the controller 100 first performs steps S31 and S32.

In step S31, the control unit 112 controls the robot 10 to move the hand link 23 to a position immediately in front of a carry-out source of the substrate W (the peripheral chamber 3 accommodating the substrate W inside). In step S32, the control unit 112 causes the robot 10 to start advancing the hand link 23 into the carry-out source.

Next, the controller 100 performs steps S33 and S34. In step S33, the calculation unit 111 acquires the first data set D1 including the information on the first posture PS1 and the position P1, based on the posture of the robot 10 and the position of the hand link 23 at the time when the sensor 60 detects the first line 42, and the posture of the robot 10 and the position of the hand link 23 at the time when the sensor 60 detects the second line 43. In step S34, the calculation unit 111 acquires the second data set D2 including the information on the second posture PS2 and the position P2, based on the posture of the robot 10 and the position of the hand link 23 at the time when the sensor 60 detects the third line 52, and the posture of the robot 10 and the position of the hand link 23 at the time when the sensor 60 detects the fourth line 53.

Next, the controller 100 performs steps S35 and S36. In step S35, the calculation unit 111 selects the reference data associated with the carry-out source into which the hand link 23 is advancing. In step S36, the calculation unit 111 calculates the length of each of the plurality of links 20 based on the first data set D1 acquired in step S33, the second data set D2 acquired in step S34, and the reference data selected in step S35.

Next, the controller 100 performs steps S37 and S38. In step S37, the control unit 112 causes the robot 10 to stop the advance of the hand link 23 into the carry-out source. In step S38, the control unit 112 causes the robot 10 to perform the transfer of the substrate W out of the carry-out source and the transfer of the substrate W to the next transfer destination.

Next, the controller 100 performs steps S41 and S42. In step S41, the control unit 112 controls the robot 10 to acquire the next substrate W (support the next substrate W by the hand 24). In step S42, the control unit 112 controls the robot 10 to move the hand link 23 to a position immediately in front of the transfer destination of the next substrate W.

Next, the controller 100 performs steps S43 and S44. In step S43, the control unit 112 causes the robot 10 to start carrying the next substrate W into the transfer destination. In step S44, the positional deviation detection unit 115 detects the positional deviation of the substrate W based on the result of detection of the substrate W by the sensor 60.

Next, the controller 100 performs steps S45, S46, and S47. In step S45, based on the calculated link length, the control unit 112 calculates the error between the actual position that the hand link 23 reaches and the hand target position. In step S46, the control unit 112 corrects the hand target position based on the positional deviation of the substrate W detected in step S44 and the error calculated in step S25. In step S47, the control unit 112 moves the hand link 23 to the corrected hand target position to place the substrate W at the target position.

### Modifications

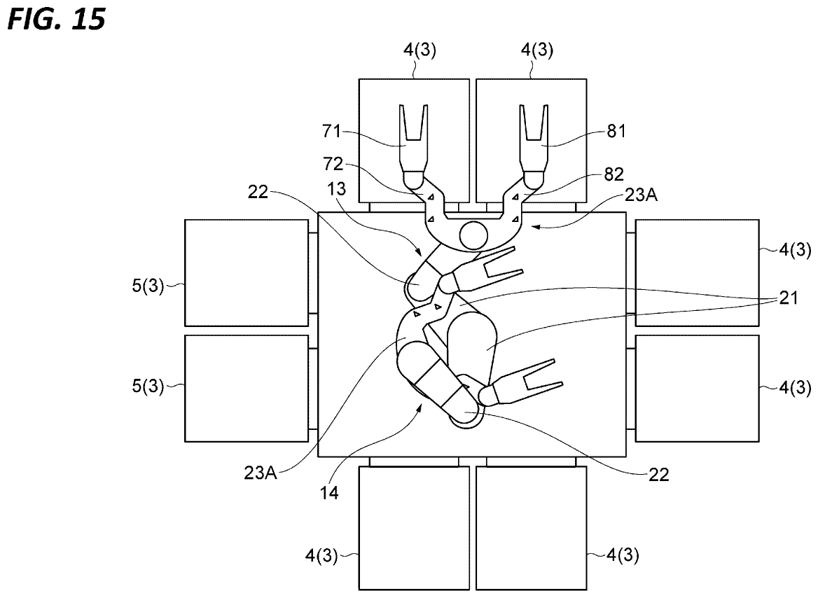

FIG. 15 is a view illustrating a modification of the semiconductor manufacturing apparatus 1. In FIG. 15, a semiconductor manufacturing apparatus 1A is a modification in which the robot 10 of the semiconductor manufacturing apparatus 1 is replaced with the robot 10A. The robot 10A is a modification in which the hand link 23 of the robot 10 is replaced with a hand link 23A. The hand link 23A includes a pair of sub-links 72 and 82. The pair of sub-links 72 and 82 include a pair of hands 71 and 81, respectively. Each of the pair of hands 71 and 81 supports the substrate W. For example, the pair of sub-links 72 and 82 extend from the joint axis Ax3 in opposite directions, and bend in the same direction at the middles thereof. A hand 71 is provided at the end of the sub-link 72, and a hand 81 is provided at the end of the sub-link 82. According to the robot 10A, the pair of hands 71 and 81 may be simultaneously moved into/out of a pair of peripheral chambers 3 adjacent to each other, respectively. Hereafter, when discriminating the pair of peripheral chambers 3 adjacent to each other, one will be referred to as a first peripheral chamber 3, and the other will be referred to as a second peripheral chamber 3.

The robot 10A may be a double-arm type with a pair of arms 13 and 14. In the double-arm type robot 10A, each of the pair of arms 13 and 14 includes the hand link 23A and the links 21 and 22. The link 21 of the arm 13 and the link 21 of the arm 14 may be fixed to each other. Each of the arms 13 and 14 performs an extend motion to move the hand link 23A away from Ax1 and a retract motion to move the hand link 23A closer to Ax1, in accordance with the rotation of the link 21 around Ax1. The extend motion allows the pair of hands 71 and 81 to move into the pair of peripheral chambers 3, respectively, and the retract motion allows the pair of hands 71 and 81 to move out of the pair of peripheral chambers 3, respectively.

The calculation unit 111 calculates the length of each of the sub-link 72 and the links 21 and 22 based on the position of the sub-link 72 in the state where the robot 10A is in a first posture and the position of the sub-link 72 in the state where the robot 10A is in a second posture different from the first posture, and calculates the length of each of the sub-link 82 and the links 21 and 22 based on the position of the sub-link 82 in the state where the robot 10A is in a third posture and the position of the sub-link 82 in the state where the robot 10A is in a fourth posture different from the third posture.

All the first, second, third, and fourth postures may be postures to simultaneously move the hands 71 and 81 into/out of the pair of peripheral chambers 3 (e.g., the pair of process chambers 4), respectively, along the predetermined entry/exit line 90. As an example, the sub-links 72 and 82 may include the first part 31 and the second part 32 described above, respectively. For example, the first posture is the posture when the first part 31 of the sub-link 72 is detected by the at least one sensor 60, and the second posture is the posture when the second part 32 of the sub-link 72 is detected by the at least one sensor 60. The third posture is the posture when the first part 31 of the sub-link 82 is detected by the at least one sensor 60, and the second posture is the posture when the second part 32 of the sub-link 82 is detected by the at least one sensor 60.

The first part 31 and the second part 32 of the sub-link 72 and the first part 31 and the second part 32 of the sub-link 82 may be provided to be detectable by different sensors 60 when the hands 71 and 81 are simultaneously moved into/out of the pair of peripheral chambers 3, respectively. For example, the first part 31 and the second part 32 of the sub-link 72 are arranged to pass the sensor 60 corresponding to the second peripheral chamber 3. The first part 31 and the second part 32 of the sub-link 82 are arranged to pass the sensor 60 corresponding to the second peripheral chamber 3. By the series of operations to simultaneously move the hands 71 and 81 into/out of the pair of peripheral chambers 3, respectively, it is possible to easily detect the position of the sub-link 72 in the first posture, the position of the sub-link 72 in the second posture, the position of the sub-link 82 in the third posture, and the position of the sub-link 82 in the fourth posture.

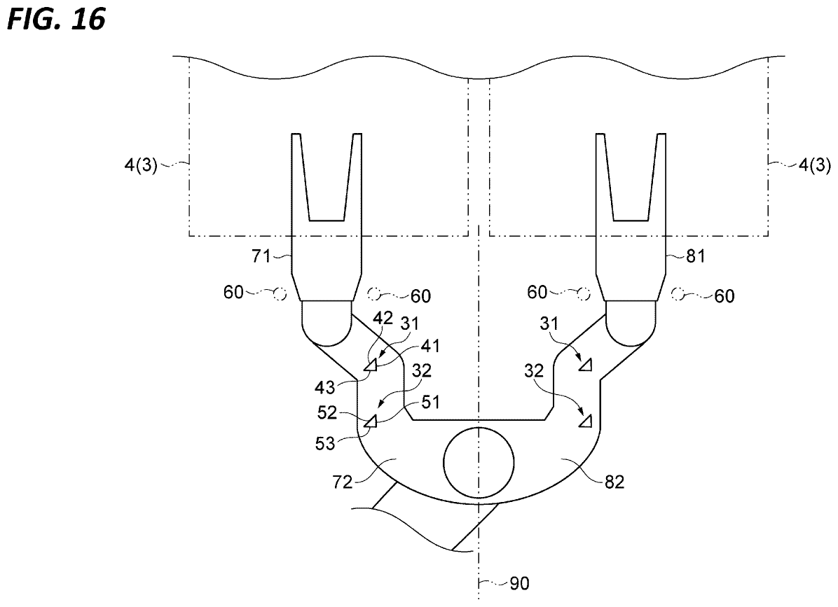

As illustrated in FIG. 16, the first part 31 of each of the sub-links 72 and 82 may include the first marker 41 described above, and the second part 32 of each of the sub-links 72 and 82 may include the second marker 51 described above. In each of the sub-links 72 and 82, the first line 42 and the second line 43 of the first marker 41 and the third line 52 and the fourth line 53 of the second marker 51 may be lined up along the entry/exit line 90. The four redundant equations described above may be obtained for each of the sub-links 72 and 82, so that the link length may be calculated with a higher accuracy.

### SUMMARY

The present disclosure has the following configuration.

(1) A substrate transfer robot system 7 including a robot 10 provided with a hand link 23 including a hand 24 supporting a substrate W and a plurality of links 20 including one or more links connected to the hand link 23; a calculation unit 111 that calculates a length of each of the plurality of links 20 of the robot 10 based on a position of the hand link 23 in a state where the robot 10 is in a first posture and a position of the hand link 23 in a state where the robot 10 is in a second posture different from the first posture; and a control unit 112 that controls the robot 10 to place the substrate W at a target position based on the calculated length of each of the plurality of links 20.

The length of the plurality of links 20 may vary due to, for example, thermal expansion. The temperature distribution in the plurality of links 20 may not be uniform. For example, a heating caused from, for example, the entry into the process chamber 4 concentrates in the hand link 23. Further, in a case where a plurality of actuators of the robot 10 is disposed collectively in the base portion of the plurality of links 20, the side of the links close to the base portion is easily affected by the heat occurring from the actuators than the side of the links farther from the base portion is. Since the temperature distribution in the plurality of links 20 varies due to the factors described above, the relationship between the links in terms of the amount of extension caused from the thermal expansion also varies. The substrate transfer robot system 7 calculates the length of each of the plurality of links 20 (hereinafter, referred to as the “link length”), based on the position of the hand link 23 in the first posture and the position of the hand link 23 in the second posture different from the first posture. Thus, even when the relationship between the links in terms of the amount of extension caused from, for example, the thermal expansion is unknown, the length of each of the plurality of links 20 may be calculated with a high reliability, and the substrate W may be placed at the target position with a high accuracy based on the calculation result. Therefore, the accuracy of placement of the substrate W may be improved effectively.

(2) The substrate transfer robot system 7 described in (1), further including at least one sensor 60 that detects the hand link 23, and a hand position detection unit 114 that detects each of the position of the hand link 23 in the first posture and the position of the hand link 23 in the second posture based on a result of detection of the hand link 23 by the at least one sensor 60.

The position of the hand link 23 in the first posture and the position of the hand link 23 in the second posture may be easily acquired using the object sensor 60.

(3) The substrate transfer robot system 7 described in (2), wherein the hand link 23 includes a first part 31 and a second part 32 at different positions from each other, and the hand position detection unit 114 detects each of the position of the hand link 23 in the first posture and the position of the hand link 23 in the second posture based on a result of detection of the first part 31 and the second part 32 by the same sensor 60.

The position of the hand link 23 in the first posture and the position of the hand link 23 in the second posture may be efficiently detected using the period of time when the robot 10 is moving the hand link 23.

(4) The substrate transfer robot system 7 described in (3), wherein both the first posture and the second posture are postures for advancing and retracting the hand link 23 along a predetermined entry/exit line 90 to move the hand 24 into/out of a process chamber 4.

The position of the hand link 23 in the first posture and the position of the hand link 23 in the second posture may be efficiently detected using the period of time when the robot 10 is moving the hand link 23.

(5) The substrate transfer robot system 7 described in any one of (2) to (4), wherein the at least one sensor 60 is at least one object sensor 60 that each detects the presence or absence of an object at a specific detection position thereof.

By using the object sensor 60, the system configuration may be simplified.

(6) The substrate transfer robot system 7 described in (5), further including a positional deviation detection unit 115 that detects a positional deviation of the substrate W based on a result of detection of the substrate W by the at least one object sensor 60, wherein the control unit 112 controls the robot 10 to place the substrate W at the target position based on the calculated length of each of the plurality of links 20 and the detected positional deviation of the substrate W.

By using the second sensor 60 for multiple purposes, the system simplification may be implemented.

(7) The substrate transfer robot system 7 described in (5) or (6), wherein the hand link 23 includes a first part 31 and a second part 32 provided at different positions from each other, and the hand position detection unit 114 detects each of the position of the hand link 23 in the first posture and the position of the hand link 23 in the second posture based on a result of detection of the first part 31 and the second part 32 by the same object sensor 60.

By the series of operations to detect the first part 31 and the second part 32 in turn by the same object sensor 60, both the position of the hand link 23 in the first posture and the position of the hand link 23 in the second posture may be detected. Therefore, both the efficiency of operation of the robot 10 and the accuracy of placement of the substrate W may be achieved.

(8) The substrate transfer robot system 7 described in (7), wherein the first part 31 includes a first marker 41 including a first line 42 and a second line 43 that intersect each other, and the hand position detection unit 114 detects the position of the hand link 23 within a plane including the first line 42 and the second line 43, as the position of the hand link 23 in the first posture, based on a result of detection of the first line 42 and the second line 43 by the same object sensor 60.

By the series of operations in which the first marker 41 passes the same object sensor 60, the position of the hand link 23 in the two intersecting directions may be acquired in a short time. Therefore, both the efficiency of operation of the robot 10 and the accuracy of placement of the substrate W may be further improved.

(9) The substrate transfer robot system 7 described in (8), wherein the second part 32 includes a second marker 51 including a third line 52 and a fourth line 53 that intersect each other, and the hand position detection unit 114 detects the position of the hand link 23 within a plane including the third line 52 and the fourth line 53, as the position of the hand link 23 in the second posture, based on a result of detection of the third line 52 and a result of detection of the fourth line 53 by the same object sensor 60.

By acquiring the redundant information identifying the length of each of the plurality of links 20, the link length may be calculated with a further enhanced reliability. Therefore, both the efficiency of operation of the robot 10 and the accuracy of placement the substrate W may be further improved.

(10) The substrate transfer robot system 7 described in any one of (7) to (9), wherein the control unit 112 controls the robot 10 to move the hand 24 into/out of a process chamber 4 along a predetermined entry/exit line 90, and the first part 31 and the second part 32 are arranged to pass the same object sensor 60 at different timings while the hand link 23 is moving along the entry/exit line 90.

By using the operation to carry the substrate W into/out of the process chamber 4, the position of the hand link 23 in the first posture and the position of the hand link 23 in the second posture may be detected. Therefore, both the efficiency of operation of the robot 10 and the accuracy of placement of the substrate W may be further improved.

(11) The substrate transfer robot system 7 described in (10), further including a positional deviation detection unit 115 that detects a positional deviation of the substrate W based on a result of detection of the substrate W by the same object sensor 60 when the substrate W supported by the hand 24 is moving along the entry/exit line 90.

By using the operation to carry the substrate W into/out of the process chamber 4, the positional deviation of the substrate W may be further detected. Therefore, both the efficiency of operation of the robot 10 and the accuracy of placement of the substrate W may be further improved.

(12) The substrate transfer robot system 7 described in any one of (4) to (11), wherein the hand position detection unit 114 detects the position of the hand link 23 in the first posture and the position of the hand link 23 in the second posture while the robot 10 is moving the hand 24 from the inside of the process chamber 4 to the outside of the process chamber 4 along the entry/exit line 90, and the control unit 112 controls the robot 10 to place the substrate W at the target position based on the calculated length of each of the plurality of links 20.

By using the operation to carry the substrate W out of the process chamber 4, the position of the hand link 23 in the first posture and the position of the hand link 23 in the second posture may be detected.

(13) The substrate transfer robot system 7 described in any one of (4) to (11), wherein the hand position detection unit 114 detects the position of the hand link 23 in the first posture and the position of the hand link 23 in the second posture while the robot 10 is moving the hand 24 from the outside of the process chamber 4 into the process chamber 4 along the entry/exit line 90 to transfer the substrate W from the inside of the process chamber 4 to the outside of the process chamber 4, and the control unit 112 controls the robot 10 to place the substrate W at the target position based on the calculated length of each of the plurality of links 20.

By using the operation to advance the hand link 23 into the process chamber 4 in order to carry the substrate W out of the process chamber 4, the position of the hand link 23 in the first posture and the position of the hand link 23 in the second posture may be detected.

(14) The substrate transfer robot system 7 described in any one of (1) to (13), wherein each of the plurality of links 20 has a reference length in a first environment, at least one of the plurality of links 20 has a length different from the reference length in a second environment different from the first environment, and the calculation unit 111 calculates the length of each of the plurality of links 20 in the second environment based on a result of detection of the position of the hand link 23 in the first posture and the position of the hand link 23 in the second posture, in the second environment.

The substrate W may be placed at the target position with a high accuracy, regardless of the difference between the first and second environments.

(15) The substrate transfer robot system 7 described in (14), wherein the calculation unit 111 calculates the length of each of the plurality of links 20 based on results of detection of the position of the hand link 23 in the first posture and the position of the hand link 23 in the second posture in both the first environment and the second environment.

The length of each of the plurality of links 20 may be calculated even when the position of the at least one sensor 60 is unknown.

(16) The substrate transfer robot system 7 described in (2), wherein the control unit 112 controls the robot 10 to advance and retract the hand link 23 along a predetermined first entry/exit line 91 to transfer the substrate W between the inside and the outside of a first process chamber 4A and to advance and retract the hand link 23 along a predetermined second entry/exit line 92 to transfer the substrate W between the inside and the outside of a second process chamber 4B, the at least one sensor 60 includes a first sensor 61 provided to detect the substrate W moving along the first entry/exit line 91 and a second sensor 62 provided to detect the substrate W moving along the second entry/exit line 92, and the hand position detection unit 114 detects the position of the hand link 23 in the first posture based on a result of detection of the hand link 23 by the first sensor 61 and the position of the hand link 23 in the second posture based on a result of detection of the hand link 23 by the second sensor 62.

The position of the hand link 23 in the first posture and the position of the hand link 23 in the second posture may be easily detected using the first object sensor 60 corresponding to the first process chamber 4A and the second object sensor 60 corresponding to the second process chamber 4B.

(17) The substrate transfer robot system 7 described in (16), further including a positional deviation detection unit 115 that detects a positional deviation of the substrate W based on a result of detection of the substrate W by the second sensor 62 when the substrate W is moving from the outside of the second process chamber 4B into the second process chamber 4B, and the control unit 112 controls the robot 10 to place the substrate W at the target position in the second process chamber 4B based on the positional deviation of the substrate W.

By using the second sensor 62 for multiple purposes, the system simplification may be implemented.

(18) The substrate transfer robot system 7 described in (6), further including a storage unit 113 that stores a program for positioning the hand link 23 at a target position of the hand 24 corresponding to the target position based on the reference length of each of the plurality of links 20, and the control unit 112 calculates an error between the actual position that the hand link 23 reaches according to the program and the target position of the hand 24 based on the calculated length of each of the plurality of links 20, corrects the target position based on the detected positional deviation of the substrate W and the calculated error, and controls the robot 10 based on the corrected target position and the program.

It is possible to speed up the calculation to place the substrate W at the target position.

(19) A semiconductor manufacturing apparatus 1 including: at least one process chamber 4 that accommodates a substrate W and performs a processing on the accommodated substrate W; a robot 10 including a hand link 23 including a hand 24 supporting the substrate W, and a plurality of links 20 including one or more links connected to the hand link 23, and transferring the substrate W to a target position in the at least one process chamber 4, a calculation unit 111 that calculates a length of each of the plurality of links 20 of the robot 10 based on a position of the hand link 23 in a state where the robot 10 is in a first posture and a position of the hand link 23 in a state where the robot 10 is in a second posture different from the first posture, and a control unit 112 that controls the robot 10 to place the substrate W at the target position based on the calculated length of each of the plurality of links 20.

(20) A control method including calculating a length of each of a plurality of links 20 of a robot 10 based on a position of a hand link 23 in a state where the robot 10 is in a first posture and a position of the hand link 23 in a state where the robot 10 is in a second posture different from the first posture, the robot 10 including the hand link 23 including a hand 24 supporting a substrate W and the plurality of links 20 including one or more links connected to the hand link 23, and controlling the robot 10 to place the substrate W at a target position based on the calculated length of each of the plurality of links 20.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate transfer robot system, comprising:
a robot provided with a hand link including a hand supporting a substrate, and a plurality of links including one or more links connected to the hand link;
a calculator configured to calculate a length of each of the plurality of links of the robot based on a position of the hand link in a state where the robot is in a first posture and a position of the hand link in a state where the robot is in a second posture different from the first posture; and
a controller configured to control the robot to place the substrate at a target position based on the length of each of the plurality of links calculated by the calculator.

2. The substrate transfer robot system according to claim 1, further comprising:
at least one sensor configured to detect the hand link; and
a hand position detector configured to detect each of the position of the hand link in the first posture and the position of the hand link in the second posture based on a result of detection of the hand link by the at least one sensor.

3. The substrate transfer robot system according to claim 2, wherein the hand link includes a first part and a second part at different positions from each other, and
the hand position detector detects each of the position of the hand link in the first posture and the position of the hand link in the second posture based on a result of detection of the first part and the second part by a same sensor.

4. The substrate transfer robot system according to claim 3, wherein both the first posture and the second posture are postures for advancing and retracting the hand link along a predetermined entry/exit line to move the hand into/out of a process chamber.

5. The substrate transfer robot system according to claim 2, wherein the at least one sensor is at least one object sensor that each detects a presence or absence of an object at a specific detection position thereof.

6. The substrate transfer robot system according to claim 5, further comprising:
a positional deviation detector configured to detect a positional deviation of the substrate based on a result of detection of the substrate by the at least one object sensor,
wherein the controller controls the robot to place the substrate at the target position based on the length of each of the plurality of links calculated by the calculator and the positional deviation of the substrate detected by the positional deviation detector.

7. The substrate transfer robot system according to claim 5, wherein the hand link includes a first part and a second part provided at different positions from each other, and
the hand position detector detects each of the position of the hand link in the first posture and the position of the hand link in the second posture based on a result of detection of the first part and the second part by a same object sensor.

8. The substrate transfer robot system according to claim 7, wherein the first part includes a first marker including a first line and a second line that intersect each other, and
the hand position detector detects the position of the hand link within a plane including the first line and the second line, as the position of the hand link in the first posture, based on a result of detection of the first line and a result of detection of the second line by the same object sensor.

9. The substrate transfer robot system according to claim 8, wherein the second part includes a second marker including a third line and a fourth line that intersect each other, and
the hand position detector detects the position of the hand link within a plane including the third line and the fourth line, as the position of the hand link in the second posture, based on a result of detection of the third line and a result of detection of the fourth line by the same object sensor.

10. The substrate transfer robot system according to claim 7, wherein the controller controls the robot to move the hand into/out of a process chamber along a predetermined entry/exit line, and
the first part and the second part are arranged to pass the same object sensor at different timings while the hand link is moving along the predetermined entry/exit line.

11. The substrate transfer robot system according to claim 10, further comprising:
a positional deviation detector configured to detect a positional deviation of the substrate based on a result of detection of the substrate supported by the hand that is moving along the predetermined entry/exit line, by the same object sensor.

12. The substrate transfer robot system according to claim 4, wherein the hand position detector detects the position of the hand link in the first posture and the position of the hand link in the second posture, while the robot is moving the hand from an inside of the process chamber to an outside of the process chamber along the predetermined entry/exit line, and
the controller controls the robot to place the substrate at the target position based on the length of each of the plurality of links calculated by the calculator.

13. The substrate transfer robot system according to claim 4, wherein the hand position detector detects the position of the hand link in the first posture and the position of the hand link in the second posture, while the robot is moving the hand from an outside of the process chamber into the process chamber along the predetermined entry/exit line to transfer the substrate from an inside of the process chamber to the outside of the process chamber, and
the controller controls the robot to place the substrate at the target position based on the length of each of the plurality of links calculated by the calculator.

14. The substrate transfer robot system according to claim 1, wherein each of the plurality of links has a reference length in a first environment,
at least one of the plurality of links has a length different from the reference length in a second environment different from the first environment, and
the calculator calculates the length of each of the plurality of links in the second environment based on a result of detection of the position of the hand link in the first posture and the position of the hand link in the second posture in the second environment.

15. The substrate transfer robot system according to claim 14, wherein the calculator calculates the length of each of the plurality of links based on a result of detection of the position of the hand link in the first posture and the position of the hand link in the second posture in both the first environment and the second environment.

16. The substrate transfer robot system according to claim 2, wherein the controller controls the robot to move the hand into/out of a first process chamber along a predetermined first entry/exit line, and move the hand into/out of a second process chamber along a predetermined second entry/exit line, and
the at least one sensor includes a first sensor provided to detect the substrate supported by the hand moving along the predetermined first entry/exit line and a second sensor provided to detect the substrate supported by the hand moving along the predetermined second entry/exit line, and
the hand position detector detects the position of the hand link in the first posture based on a result of detection of the hand link by the first sensor, and the position of the hand link in the second posture based on a result of detection of the hand link by the second sensor.

17. The substrate transfer robot system according to claim 1, wherein the hand link includes
a first sub-link including the hand,
a second sub-link including a second hand supporting the substrate at a position away from the hand, and
the calculator calculates
a length of each of the first sub-link and the one or more links based on a position of the first sub-link in a state where the robot is in the first posture, and a position of the first sub-link in a state where the robot is in the second posture different from the first posture, and
a length of each of the second sub-link and the one or more links based on a position of the second sub-link in a state where the robot is in a third posture and a position of the second sub-link in a state where the robot is in a fourth posture different from the third posture.

18. The substrate transfer robot system according to claim 17, wherein all the first posture, the second posture, the third posture, and the fourth posture are postures to simultaneously move the hand and the second hand into/out of a first process chamber and a second process chamber, respectively, along a predetermined entry/exit line.

19. A semiconductor manufacturing apparatus comprising:
at least one process chamber accommodating a substrate, and configured to perform a processing on the substrate accommodated in the at least one process chamber;
a robot provided with a hand link including a hand supporting the substrate, and a plurality of links including one or more links connected to the hand link, and configured to transfer the substrate to a target position in the at least one process chamber;
a calculator configured to calculate a length of each of the plurality of links of the robot based on a position of the hand link in a state where the robot is in a first posture and a position of the hand link in a state where the robot is in a second posture different from the first posture, and
a controller configured to control the robot to place the substrate at the target position based on the length of each of the plurality of links calculated by the calculator.

20. A control method comprising:
calculating a length of each of a plurality of links of a robot based on a position of a hand link in a state where the robot is in a first posture and a position of the hand link in a state where the robot is in a second posture different from the first posture, the robot provided with the hand link including a hand supporting a substrate and the plurality of links including one or more links connected to the hand link; and
controlling the robot to place the substrate at a target position based on the length of each of the plurality of links calculated in the calculating.
